(19) United States
(12) Patent Application Publication
(10) Pub. No.: US 2017/0213734 A9
(43) Pub. Date: Jul. 27, 2017

(54) MULTIFREQUENCY CAPACITIVELY COUPLED PLASMA ETCH CHAMBER

(71) Applicants: Alexei Marakhtanov, Albany, CA (US); Rajinder Dhindsa, San Jose, CA (US); Akira Koshiishi, San Jose, CA (US); Andreas Fischer, Castro Valley, CA (US)

(72) Inventors: Alexei Marakhtanov, Albany, CA (US); Rajinder Dhindsa, San Jose, CA (US); Akira Koshiishi, San Jose, CA (US); Andreas Fischer, Castro Valley, CA (US)

(21) Appl. No.: 12/533,984

(22) Filed: Jul. 31, 2009

Related U.S. Application Data
(63) Continuation-in-part of application No. 12/047,813, filed on Mar. 13, 2008, now Pat. No. 8,450,635.
(60) Provisional application No. 61/166,994, filed on Apr. 6, 2009.
(60) Provisional application No. 60/909,353, filed on Mar. 30, 2007.

(51) Int. Cl. H01L 21/306; C23C 16/513

(52) U.S. Cl. CPC H01L 21/2633

(57) ABSTRACT

A plasma processing system for use with a gas. The plasma processing system comprises a first electrode, a second electrode, a gas input port, a power source and a passive circuit. The gas input port is operable to provide the gas between the first electrode and the second electrode. The power source is operable to ignite plasma from the gas between the first electrode and the second electrode. The passive circuit is coupled to the second electrode and is configured to adjust one or more of an impedance, a voltage potential, and a DC bias potential of the second electrode. The passive radio frequency circuit comprises a capacitor arranged in parallel with an inductor.

The present application claims benefit under 35 U.S.C. §119 (e) to U.S. provisional patent application 61/166,994, filed Apr. 6, 2009, the entire disclosure of which is incorporated herein by reference.

### BACKGROUND

Advances in plasma processing have facilitated growth in the semiconductor industry. Plasma processing may involve different plasma generating technologies, for example, inductively coupled plasma processing systems, capacitively-coupled plasma processing systems, microwave generated plasma processing systems and the like. Manufacturers often employ capacitively-coupled plasma processing systems in processes that involve etching and/or depositing of materials to manufacture semiconductor devices.

Next-generation semiconductor devices being fabricated with new advanced materials, complex stacks of dissimilar materials, thinner layers, smaller features, and tighter tolerances may require plasma processing systems with more exact control and wider operating windows for plasma process parameters. Thus, an important consideration for plasma processing of substrates involves capacitively-coupled plasma processing systems possessing capabilities to control a plurality of plasma related process parameters. Conventional methods to control plasma related process parameters may include a passive RF coupling circuit, a radio frequency (RF) generator or a DC power source.

FIG. 1A illustrates a simplified schematic of a prior art plasma processing system 100 during a plasma etching process. Plasma processing system 100 includes a confinement chamber 102, upper electrode 104, a lower electrode 106 and an RF driver 108. Confinement chamber 102, upper electrode 104 and lower electrode 106 are arranged to provide a plasma-forming space 110. RF driver 108 is electrically connected to lower electrode 106, while upper electrode 104 is electrically connected to ground.

In operation, a substrate 112 is held on lower electrode 106 via an electrostatic force. A gas source (not shown) supplies an etching gas to plasma-forming space 110. RF driver 108 provides a driving signal to lower electrode 106, thus providing a voltage differential between lower electrode 106 and upper electrode 104. The voltage differential creates an electromagnetic field in plasma-forming space 110, wherein the gas in plasma-forming space 110 is ionized, forming plasma 114. Plasma 114 etches the surface of substrate 112.

FIG. 1B illustrates a magnified view of the bottom portion of plasma processing system 100 during a conventional etching process. As shown in the figure, a plasma sheath 116 is formed between plasma 114 and the surface of substrate 112. Plasma sheath 116 bears the potential drop between the potential of plasma 114 and the potential of lower electrode 106. Plasma ions 118 from plasma 114 are accelerated toward the surface of substrate 112 via the potential drop across plasma sheath 116. The bombardment of substrate 112 with plasma ions 118 causes material on the surface of substrate 112 to be etched away. During the etching process, the flux of neutral species along with ions from plasma also causes a polymer layer to be deposited on substrate 112. In this manner, plasma 114 may be used to etch and/or deposit materials onto substrate 112 in order to create electronic devices.

In reality, the need to precisely control plasma processing parameters and etching/deposition behavior require that plasma processing systems be more complex than that of plasma processing system 100 of FIGS. 1A & 1B.

FIG. 2 shows a simplified schematic of a prior art plasma processing system 200. As illustrated in FIG. 2, plasma processing system 200 includes an upper electrode 204, a lower electrode 206, a grounded upper extension ring 210, an upper insulator 212, a grounded bottom extension ring 214, a bottom insulator 216, an RF matching circuit 218, an RF generator 220, an RF matching circuit 222 and an RF generator 224.

The basic setup of plasma processing system 200 of FIG. 2 is similar to the aforementioned plasma processing system 100 of FIG. 1A, but differs in that instead of upper electrode 204 being grounded, it is connected to RF generator 224 via RF matching circuit 222. In this manner the RF bias of upper electrode 204 can be independently controlled. Also, plasma processing system 200 contains grounded upper and bottom extension rings that drain RF current from the plasma boundaries. In the example of plasma processing system 200, lower electrode 206 is electrically isolated from grounded bottom extension ring 214 by bottom insulator 216. Similarly, upper electrode 204 is electrically isolated from a grounded upper extension ring 210 by upper insulator 212.

Plasma processing system 200 may be a single, double (DFC), or triple frequency RF capacitively discharge system. Non-limiting examples of radio frequencies provided by RF generator 224 include 2, 27 and 60 MHz. In plasma processing system 200, a substrate 208 may be disposed above lower electrode 206 for processing.

Consider the situation wherein, for example, substrate 208 is being processed. During plasma processing, RF generator 220 with a path to ground may supply a low power RF bias to lower electrode 206 through RF matching circuit 218. As an example, RF matching circuit 218 may be used to maximize power delivery to plasma processing system 200. The driving signal from RF generator 220 provided to lower electrode 206 provides a voltage differential between lower electrode 206 and upper electrode 204. The voltage differential creates an electromagnetic field which causes a gas to become ionized, thereby generating a plasma between upper electrode 204 and lower electrode 206 (the gas and the plasma are not shown to simplify schematic). The plasma may be used to etch and/or deposit materials onto substrate 208 to create electronic devices.

Consider the situation, wherein, for example, a manufacturer may want to adjust the voltage of upper electrode 204 during the etching process to provide additional control over plasma processing parameters. The voltage of upper electrode 204 may be adjusted by RF generator 224 through RF matching circuit 222 with a path to ground. RF generator 224, in the example of FIG. 2, may be high powered.

Another type of prior art plasma processing system will now be described with reference to FIG. 3.

FIG. 3 shows a simplified schematic of a prior art plasma processing system 300. As illustrated in FIG. 3, plasma processing system 300 includes upper electrode 204, lower electrode 206, grounded upper extension ring 210, upper insulator 212, grounded bottom extension ring 214, bottom insulator 216, RF matching circuit 218, RF generator 220, an RF filter 322 and a DC power source 324. In plasma processing system 300, substrate 208 may be disposed above lower electrode 206 for processing.

Plasma processing system 300 of FIG. 3 is similar to the aforementioned multi-frequency capacitively-couple plasma processing system 200 of FIG. 2, but differs in the extent that in the example of FIG. 3, DC power source 324 is coupled to upper electrode 204 through RF filter 322 with a path to ground. RF filter 322 is generally used to provide attenuation of unwanted harmonic RF energy without introducing losses to DC power source 324. Unwanted harmonic RF energy is generated when the plasma discharges and may be kept from being returned to the DC power source by RF filter 322.

Consider the situation wherein, for example, a manufacturer may want to adjust the DC potential of upper electrode 204 during plasma processing to provide additional control over plasma processing parameters. The DC potential of upper electrode 204, in the example of FIG. 3, may be adjusted by employing DC power source 324. Typically the purpose of applying a DC bias on upper electrode 204 would be to prevent electrons from going to upper electrode 204, therefore keeping them captured in the plasma. In this manner, the plasma density can be increased, which thereby increases the etch rate of the material of substrate 208.

The aforementioned plasma processing systems require employing an external RF and/or DC power supply to adjust the voltage on the upper electrode to attain additional control over plasma-related parameters. Since the requirement of external power sources may be expensive to implement, plasma processing systems that use an RF coupling circuit with a DC current path to ground in order to achieve RF coupling and DC bias have been developed. This type of prior art plasma processing system will now be described with reference to FIGS. 4 and 5.

FIG. 4 shows a simplified schematic of a conventional plasma processing system 400. As illustrated in FIG. 4, plasma processing system 400 includes upper electrode 204, lower electrode 206, a grounded upper extension ring 404, upper insulator 212, a grounded bottom extension ring 412, bottom insulator 216, RF matching circuit 218, RF generator 220, a conductive coupling member 410 and an RF coupling circuit 402. In plasma processing system 400, substrate 208 may be disposed above lower electrode 206 for processing.

Plasma processing system 400 of FIG. 4 is similar to the aforementioned multi-frequency capacitively-coupled plasma processing systems 200 and 300 of FIG. 2 and FIG. 3, but differs in that in the example of FIG. 4, upper electrode 204 is connected to a passive circuit (RF coupling circuit 402) instead of an external RF or DC source. Specifically, RF coupling circuit 402 is coupled to upper electrode 204 with a path to DC ground. Instead of using external power sources as done in the examples of in FIG. 2 and FIG. 3, in FIG. 4, RF coupling and DC bias to upper electrode 204 is achieved by providing a DC current return to ground and RF coupling circuit 402.

Plasma processing system 400 of FIG. 4 also differs from the examples of FIG. 2 and FIG. 3 in that in plasma processing system 400, the various extension rings are different, as will be further discussed below.

In plasma processing system 400, upper electrode 204 is electrically isolated from grounded upper electrode extension ring 404 by upper insulator 112. Grounded upper electrode extension ring 404 may be constructed of a conductive aluminum material that is covered with a quartz layer 414 on the surface. Similarly, lower electrode 206 is electrically isolated from DC grounded bottom extension ring 412 by bottom insulator 216. Grounded bottom extension ring 412 may be constructed of conductive aluminum material that may be covered with a quartz layer 416 on the surface. Other conductive materials may also be employed in the construction of lower electrode extension ring 412.

Conductive coupling member 410 is disposed above the aluminum portion of lower electrode extension ring 412 to provide a path for DC current return to ground. Conductive coupling member 410 may be constructed of silicon. Alternatively, conductive coupling member 410 may also be constructed of other conductive materials. In plasma processing system 400, conductive coupling member 410 is a ring shape. The ring shape advantageously provides radial uniformity for DC current return to ground at the bottom of the plasma processing chamber. However, conductive coupling member 410 may be formed into any appropriate shape, e.g., a circular disc shape, a doughnut shape and the like, that may provide uniformity for DC current return to ground.

Upper electrode 204 is provided with RF coupling circuit 402 that controls the RF coupling to ground. RF coupling circuit 402 does not require a power supply, i.e., RF coupling circuit 402 is a passive circuit. RF coupling circuit 402 may be configured with a circuit to vary the impedance and/or the resistance to change the RF voltage potential and/or the DC bias potential on upper electrode 204, respectively. A prior art example RF coupling circuit 402 will now be described with reference to FIG. 5.

FIG. 5 is an exploded view of an example RF coupling circuit 402. As illustrated in FIG. 5, RF coupling circuit 402 includes an inductor 502, a variable capacitor 504, an RF filter 506, a variable resistor 508 and a switch 510. RF coupling circuit 402 is configured with inductor 502 in series with variable capacitor 504 with a path to ground for generating a variable impedance output. Non-limiting example capacitance values of variable capacitor 504 include between about 20 pF to about 4,000 pF, when the operating frequency is about 2 MHz. A non-limiting example of an inductance value of inductor 502 is about 14 nH.

RF filter 506 is connected to variable resistor 508 and switch 510 for generating a variable resistance output. When switch 510 is open, upper electrode 204 of FIG. 4 is floating and there is no DC current path. When switch 510 is closed, a current path tends to flow from upper electrode 304 through the plasma (not shown) to DC grounded bottom extension ring 412 via conductive coupling member 410 of FIG. 4.

Variable capacitor 504 and inductor 502 are disposed in the current path thereby providing the impedance to the current flow. The impedance of RF coupling circuit 402 may be adjusted by changing the value of variable capacitor 504. The RF voltage potential of upper electrode 204 of FIG. 4 may be controlled by changing the impedance through inductor 502 and variable capacitor 504 of RF coupling circuit 402. As mentioned previously, RF coupling circuit 302 is a passive circuit and therefore does not require a power supply.

Furthermore, variable resistor 508 is disposed in the current path to provide resistance to the current flow. The resistance of RF coupling circuit 402 may be adjusted by changing the value of variable resistor 508. Thus, the DC potential of upper electrode 204 of FIG. 4 may be controlled to provide gradation in the DC potential values between DC floating, in which switch 510 of FIG. 5 is opened, and DC ground, in which switch 510 of FIG. 5 is closed.

RF coupling circuit 402 provides methods and arrangements for controlling plasma process parameters (e.g., plasma density, ion energy, and chemistry) by adjusting the RF impedance and/or the DC bias potential on upper electrode 204 by employing RF coupling with a DC current path to ground. Control may be achieved without employing any external power supply source.

Future generations of plasma etchers will require scaling of geometrical dimensions of hardware and good transferability of current processes for large substrate diameters. Unfortunately, the aforementioned plasma processing systems do not offer sufficient scaling and transferability of current processes for large substrate diameters. What is needed is a plasma processing system that provides scaling and transferability of current processes for large substrate diameters while allowing control over plasma related parameters.

### BRIEF SUMMARY

It is an object of the present invention to provide a capacitively coupled plasma processing system which provides scaling and transferability of current processes, control of plasma uniformity, density, and radial distribution for large substrate diameters.

An aspect of the present invention is drawn to a plasma processing system for use with a gas. The plasma processing system comprises a first electrode, a second electrode, a gas input port, a power source and a passive circuit. The gas input port is operable to provide the gas between the first electrode and the second electrode. The power source is operable to ignite plasma from the gas between the first electrode and the second electrode. The passive circuit is coupled to the second electrode and is configured to adjust one or more of an impedance, a voltage potential, and a DC bias potential of the second electrode. The passive radio frequency circuit comprises a capacitor arranged in parallel with an inductor.

Additional objects, advantages and novel features of the invention are set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate an exemplary embodiment of the present invention and, together with the description, serve to explain the principles of the invention. In the drawings:

FIG. 1A illustrates a simplified schematic of a prior art plasma processing system during a plasma etching process;

FIG. 1B illustrates a magnified view of the bottom portion of plasma processing system of FIG. 1A during a conventional etching process;

FIG. 2 shows a simplified schematic of a prior art plasma processing system with an RF generator coupled to an upper electrode;

FIG. 3 illustrates a prior art plasma processing system with a DC power source connected to an upper electrode;

FIG. 4 illustrates a prior art plasma processing system with an RF circuit arrangement coupled to an upper electrode with a path to DC ground;

FIG. 5 illustrates a simplified schematic of an RF circuit arrangement;

FIG. 6 shows, in accordance with an embodiment of the present invention, a simplified schematic for a plasma processing system containing an upper electrode coupled to a resonant filter circuit arrangement with a path to DC ground through an inductor;

FIG. 7 illustrates, in accordance with an embodiment of the present invention, a graph representing data showing the measured effects of etch rate on a substrate versus the radius or distance away from the center of the substrate compared to the etch rate for a similarly configured system except with a floating upper electrode;

FIG. 8 illustrates, in accordance with an embodiment of the present invention, a graph representing data showing the impedance of a resonant filter circuit with a path to DC ground versus the capacitance value of a variable capacitor, a component of resonant filter;

FIG. 9 illustrates, in accordance with an embodiment of the present invention, a graph representing data showing the DC voltage of a lower electrode and the RF voltage of an upper electrode versus the capacitance value of a variable capacitor, a component of the resonant RF circuit.

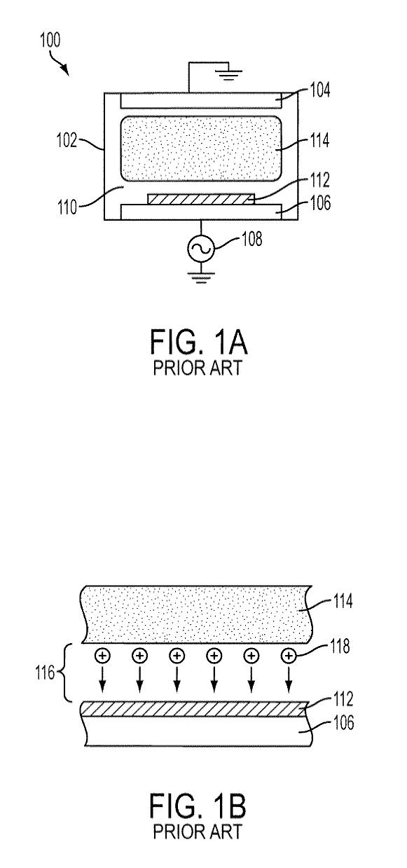

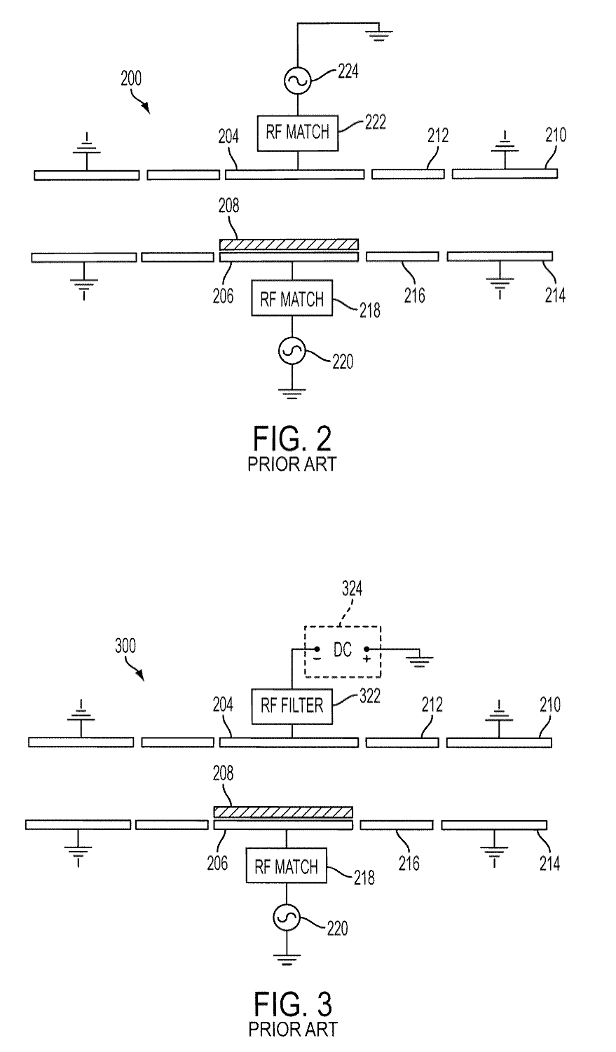

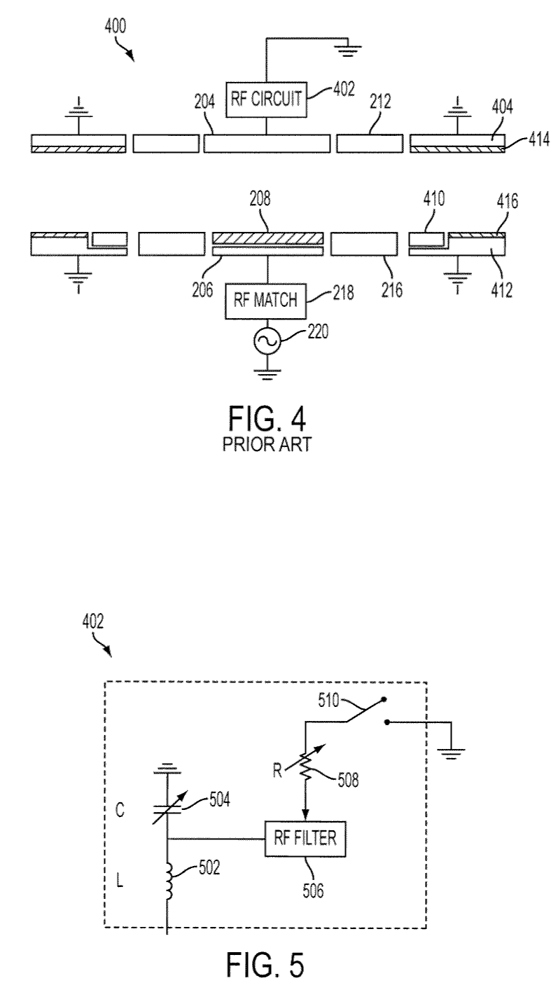

### DETAILED DESCRIPTION

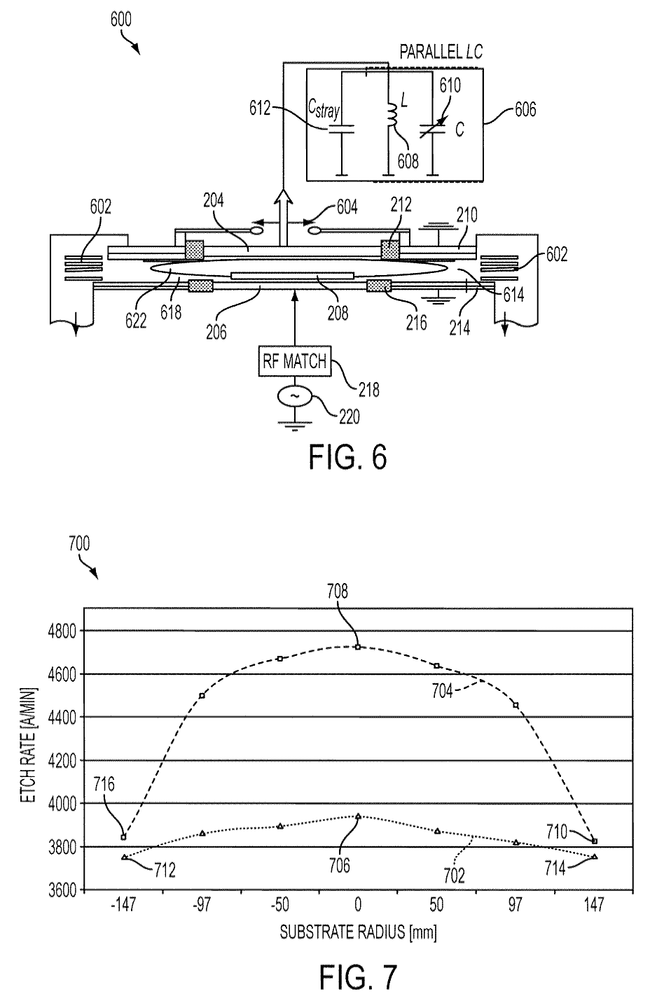

FIG. 6 illustrates a plasma processing system 600 in accordance with an example embodiment of the present invention. As illustrated in FIG. 6, plasma processing system 600 includes upper electrode 204, lower electrode 206, RF matching circuit 218, RF generator 220, upper insulator 212, bottom insulator 216, grounded bottom extension ring 214, grounded upper extension ring 210, a set of confinement rings 602, an RF ground device 604 and a resonant filter 606. Resonant filter 606 includes an inductor 608, a variable capacitor 610 and a stray capacitance 612. In plasma processing system 600, a substrate 208 may be disposed above lower electrode 206 for processing.

RF generator 220 provides RF power to lower electrode 206 through RF matching circuit 218. Non-limiting examples of radio frequencies supplied by RF generator 220 include 2, 27 and 60 MHz.

Upper electrode 204 opposes lower electrode 206 and is capacitively coupled thereto. Upper electrode 204 is additionally coupled to ground and electrically isolated from grounded upper extension ring 210 by upper insulator 112. Lower electrode 206 is coupled to ground and electrically isolated from grounded bottom extension ring 214 by bottom insulator 216.

Upper electrode 204 is able to couple to resonant filter 606. Upper electrode 104 is also able to be grounded via RF ground device 604. Stray capacitance 612 is defined as parasitic capacitance of electrode 204 to ground. Inductor 608 and variable capacitor 610 are arranged in parallel with one another and are each connected to ground.

In operation, a gas 614 is provided, by a gas source (not shown) into a plasma forming space 618. A driving signal is provided by RF generator 220 through RF matching circuit 218 to lower electrode 206. The driving signal creates an electromagnetic field between upper electrode 204 and lower electrode 206, which turns gas 614 within plasma forming space 618 into plasma 622. Plasma 622 may then be used to etch substrate 208 for creating electronic devices.

The impedance of resonant filter 606 can be controlled by varying the capacitance of variable capacitor 610. By adjusting the impedance of resonant filter 606, the low frequency RF current path between upper electrode 604 and grounded upper extension ring 610 can be controlled. Also, modifying the impedance of resonant filter 606 modifies upper electrode 204's RF voltage and phase relationship between the upper and lower sheaths of plasma 622. In this manner, plasma processing parameters such as the shape and density of plasma 622 can be controlled by simply adjusting the impedance of resonant filter 606.

For example, if the impedance of the resonant filter 606 is high, low frequency RF current is blocked from going into upper electrode 204, developing large electrode DC self-bias. In this case with provided DC current path through plasma between upper electrode 204 and grounded upper (210) and lower (214) grounded extension rings, plasma sheath may not collapse at upper electrode 204 during rf cycle. Therefore, the electrons approaching electrode 204 can be reflected back into plasma and remain captured in plasma, producing more ionization and, therefore, increasing plasma density. Also by tuning the resonant filter, both top and bottom plasma sheaths can be run at nearly in-phase condition, resulting in trapping of electrons in the plasma bulk, and, therefore, plasma density enhancement. The local increase in plasma density will therefore cause a local increase in the etch rate of substrate 208. Thus, in this fashion, a properly tuned resonant filter 606 may have the same effect of applying a DC bias to upper electrode 204, as done in prior art plasma processing system 300 in FIG. 3.

In this manner, by simply tuning the impedance of resonant filter 606, it is possible to control the radial distribution of plasma 622 above substrate 208, and therefore control the radial distribution of plasma processing parameters such as etch rate. This will be discussed further below in reference to FIG. 7.

FIG. 7 compares the etch rate as a function of substrate radius for a plasma processing system with a floating upper electrode 204 and for an example plasma processing system in accordance with the present invention (in which upper electrode 204 is coupled to resonant filter 606). The figure includes a graph 700, wherein the x-axis is substrate radius (in mm), and the y-axis is the etch rate of substrate 208 (in Å/min). Graph 700 includes a dotted function 702 and a dashed function 704. Dotted function 702 represents an etch rate as a function of substrate radius for a plasma processing system in which upper electrode 204 is floating. Dashed function 704 represents an etch rate as a function of wafer radius in accordance with an aspect of the present invention, in which upper electrode 204 is coupled to resonant filter 606.

Dotted function 702 features a maximum etch rate of approximately 3950 Å/min, indicated by point 706, at the center of the substrate, i.e., a substrate radius of 0 mm. Dotted function 702 decreases as the radius increases, to a minimum etch rate of approximately 3750 Å/min at ±147 mm from the center of the substrate, indicated by points 712 and 714.

Dashed function 704 features a maximum etch rate of approximately 4750 Å/min, indicated by point 708, at the center of the substrate, i.e., a wafer radius of 0 mm. Dashed function 704 decreases as the radius increases, to a minimum etch rate of approximately 3850 Å/min at ±147 mm from the center of the substrate, indicated by points 710 and 716.

It is clear from graph 700 that the maximum etch rates for the plasma processing system with floating upper electrode and the example plasma processing system in accordance with the present invention are achieved at the center of the substrate. It is further clear from graph 700 that the etch rates for the plasma processing system with floating upper electrode 204 and the example plasma processing system in accordance with the present invention decrease as the distance from the center of the substrate increases. However, the key point here is how the radial distribution of the etch rate changes as a result of implementing resonant filter 606 to upper electrode 204.

The etch rate at the center of the substrate, i.e., point 708, of the example plasma processing system in accordance with the present invention is approximately 20% more than the etch rate at the center of the substrate, i.e., point 706, of the plasma processing system with floating upper electrode 204. The etch rate at the substrate edges, radius off 147 mm, i.e., points 716 and 710, of the example plasma processing system in accordance with the present invention is approximately 2.7% more than the etch rate at a substrate radius of ±147 mm, i.e., points 712 and 714, of the plasma processing system with upper electrode 204 floating. Therefore, it is clear that here, the effect of resonant filter 606 coupled to upper electrode 204 was mainly to increase the etch rate in the center of substrate.

Although maintaining radial uniformity of etch rate is typically the goal in most plasma processing applications, having the ability to increase the etch rate preferentially in the center of the substrate may be useful in many cases. For instance, in the cases where plasma processing system 600 nominally provides an etch rate that results in lower etch rate in the center, by implementing a properly tuned resonant filter 606, one can compensate for this effect and thereby produce an end result that has uniform etch rate over the entire substrate.

In essence, in plasma processing system 600, one has the ability to modify the shape of the graph for the etch rate versus radius simply by tuning resonant filter 606. This capability allows the etch rate to be tuned or matched with the remainder of plasma processing system 600 in order to provide a processed substrate with an increased etch rate and uniform etch profile across the entire diameter.

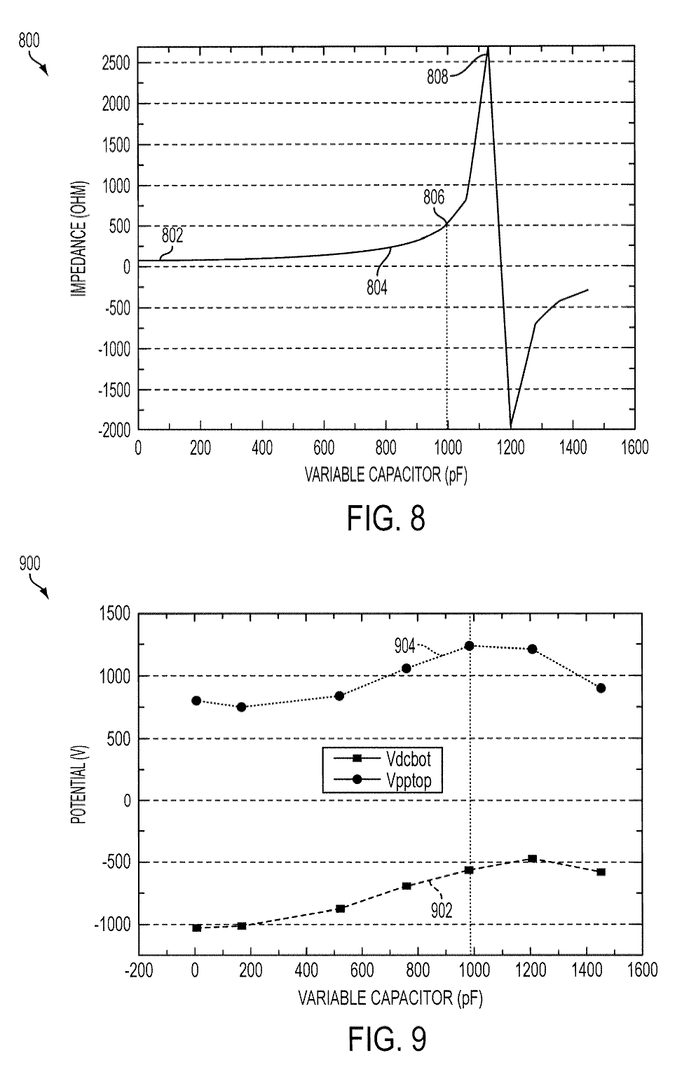

FIG. 8 illustrates a graph of the impedance of resonant filter 606 as a function 800 of the capacitance of variable capacitor 610. As illustrated in FIG. 8, the x-axis of the graph represents the capacitance of variable capacitor 610 (0 pF, 1450 pf), whereas the y-axis of the graph represents the impedance of resonant filter 606 (−2000Ω, 2500Ω). The RF frequency in this case here is around 2 MHz.

As illustrated in the figure, the impedance of resonant filter 606 gradually increases from point 802, where variable capacitor 610 has close to no capacitance, to point 804, where variable capacitor 610 has approximately a 800 pF capacitance. Then the impedance of resonant filter 606 increases more drastically from point 804, to point 806, where variable capacitor 610 has approximately a 1000 pF capacitance. Then the impedance of resonant filter 606 asymptotically increases from point 806, to point 808, where variable'capacitor 610 has approximately 1200 pF capacitance.

As discussed previously, the effect of high impedance of resonant filter 606 is to increase plasma density and substrate etch rate, mostly in the center of substrate. Therefore, in order to be able to increase the etch rate preferentially in the center (as done in the case of dashed function 704 of FIG. 7), one can configure variable capacitor 610 to result in the maximum impedance which allows a stable plasma 622 to be maintained. In FIG. 8, it is clear that point 808 (corresponding to a capacitance value of 1200 pF) gives the maximum possible impedance for resonant filter 606; however, since it is a very unstable point it may be difficult to maintain plasma 622 under that condition. A more suitable choice would be one which results in less impedance value but still allows plasma 622 to be maintained. An example of a suitable choice here could be point 806, which corresponds to capacitor value of approximately 1000 pF.

FIG. 9 is a graph of potential as a function of the capacitance of variable capacitor 610. As illustrated in FIG. 8, the x-axis of the graph represents the capacitance of variable capacitor 610 (0 pF, 1450 pf), whereas the y-axis of the graph represents potential (−1000 V, 1500 V).

As illustrated in FIG. 9, dashed line 902 represents the DC bias of lower electrode 206 as a function of the capacitance of variable capacitor 610, whereas dotted line 904 represents the peak-to-peak rf voltage of upper electrode 204 as a function of the capacitance of variable capacitor 610. The graph illustrates how the DC voltage of lower electrode 206 and the peak-to-peak voltage of upper electrode 204 can be modified by simply varying the value of variable capacitor 610. It also shows how the capacitance value corresponding to point 806 in FIG. 8 (where variable capacitor 610=1000 pF) results in maximum peak-to-peak voltage on upper electrode while also maintaining relatively high value of DC bias on lower electrode 206.

As may be appreciated from the foregoing, embodiments of the invention provide methods and arrangements for controlling plasma parameters (e.g., plasma density, ion energy, and chemistry) by adjusting the RF impedance on upper electrode 204 employing resonant filter 606 circuit with a DC current path to ground via inductor 608. Resonant filter 606 circuit and the DC ground path are relatively simple to implement. Also, control may be achieved without employing a DC power supply source. By eliminating the need for a power source, cost saving may be realized while maintaining control of plasma processing in a capacitively-coupled plasma processing chamber.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The exemplary embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed as new and desired to be protected by Letters Patent of the United States is:

1. A plasma processing system for use with a gas, said plasma processing system comprising:
a first electrode;
a second electrode;
a gas input port operable to provide the gas between said first electrode and said second electrode;
a power source operable to ignite plasma from the gas between said first electrode and said second electrode; and
a passive circuit coupled to said second electrode and being configured to adjust one or more of an impedance, a voltage potential, and a DC bias potential of said second electrode,
wherein said passive radio frequency circuit comprises a capacitor arranged in parallel with an inductor.

2. The plasma processing system of claim 1, wherein said capacitor and said inductor are each connected to ground.

3. The plasma processing system claim of 2, wherein said capacitor is a variable capacitor.

4. The plasma processing system of claim 1, further comprising a switch operable to disconnect said second electrode from said passive circuit and to connect said second electrode to ground.

5. The plasma processing system of claim 2, further comprising a switch operable to disconnect said second electrode from said passive circuit and to connect said second electrode to ground.

6. The plasma processing system of claim 3, further comprising a switch operable to disconnect said second electrode from said passive circuit and to connect said second electrode to ground.

7. A plasma processing method comprising:
providing a gas between a first electrode and a second electrode;
igniting plasma, via a power source, from the gas between the first electrode and the second electrode; and
modifying, via a passive circuit comprising a capacitor arranged in parallel with an inductor, one or more of an impedance, a voltage potential, and a DC bias potential of the second electrode.
